(19) United States
(12) Patent Application Publication
(10) Pub. No.: US 2025/0001546 A1
(43) Pub. Date: Jan. 2, 2025

(54) DOUBLE-SIDED POLISHING OF SEMICONDUCTOR WAFERS WITH DYNAMIC CONTROL

(71) Applicant: GlobalWafers Co., Ltd., Hsinchu (TW)

(72) Inventors: Yung Hsing Chu, Hsinchu (TW); Yau Ching Yang, Hsinchu (TW); Tsung Chieh Lin, Hsinchu (TW); Meng Hung Li, Hsinchu (TW); Liang Chin Chen, Hsinchu (TW)

(21) Appl. No.: 18/342,172

(22) Filed: Jun. 27, 2023

(51) Int. Cl. B24B 37/013; B24B 37/04

(52) U.S. Cl. CPC B24B 37/013; B24B 37/042; B24B 37/28

(57) ABSTRACT

A polishing apparatus for double-sided polishing of semiconductor wafers including a first platen, a second platen, a wafer carrier, and a controller is disclosed. The controller is configured to perform operations including determining whether a batch of the semiconductor wafers is loaded on the wafer carrier for double-sided polishing and retrieving specification for the batch of semiconductor wafers. The operations include based on the retrieved specification, determining an amount of tuning required for one or more flatness control parameters, and based on the amount of tuning required for the one or more flatness control parameters, identifying, or generating a recipe to perform the double-sided polishing on the batch of the semiconductor wafers. The operations include storing statistical process control (SPC) feedback data in a database to perform one or more additional iterations of the double-sided polishing on the batch of the semiconductor wafers.

### FIELD

This disclosure relates to polishing of semiconductor wafers and more particularly to systems and methods for double-sided polishing of semiconductor wafers using dynamic control.

### BACKGROUND

Semiconductor wafers are commonly used in the production of integrated circuit (IC) chips on which circuitry is printed. The circuitry is first printed in miniaturized form onto surfaces of the wafers. The wafers are then broken into circuit chips. This miniaturized circuitry requires that front and back surfaces of the wafer be extremely flat and parallel to ensure that the circuitry can be properly printed over the entire surface of the wafer. Flatness of the wafer surface on which circuits are to be printed is critical in order to maintain resolution of the lines, which can be as thin as 0.13 microns (5.1 microinches) or less. The need for a flat wafer surface, and in particular local flatness in discrete areas on the surface, is heightened when stepper lithographic processing, such as an electron beam-lithographic or photolithographic process (hereinafter “lithography”), is employed. To accomplish this, grinding and polishing processes are commonly used to improve flatness and parallelism of the front and back surfaces of the wafer after the wafer is cut from an ingot.

A particularly good finish is required when polishing the wafer in preparation for printing the miniaturized circuits on the wafer by lithography. The wafer surface on which the miniaturized circuits are to be printed must be flat. Typically, flatness of the polished surfaces of the wafer are acceptable when a new polishing pad is used on the wafer, but the flatness becomes unacceptable as the polishing pad wears down over the course of polishing many wafers.

The construction and operation of conventional polishing machines contribute to the unacceptable flatness parameters. Polishing machines typically include a circular or annular polishing pad mounted on a turntable or platen for driven rotation about a vertical axis passing through the center of the pad. A polishing slurry, typically including chemical polishing agents and abrasive particles, is applied to the pad for greater polishing interaction between the polishing pad and the surface of the wafer. This type of polishing operation is typically referred to as chemical-mechanical polishing or simply CMP.

During operation, the pad is rotated, and the wafer is brought into contact with the pad. As the pad wears, e.g., after a few hundred wafers, wafer flatness parameters degrade because the pad is no longer flat, but instead has a worn annular band forming a depression along the polishing surface of the pad. Such pad wear impacts wafer flatness and may cause “dishing” or “doming.”

As illustrated in FIG. 1, “doming,” results in the wafer 50 having a generally convex polished surface 52. The convex surface 52 may be caused by a worn pad removing less material from the center of the front surface of the wafer 50 than from the areas closer to the wafer's edge 54. This is because the worn pad's removal rate is inverse to its wear. In other words, the portions of the worn pad with less wear remove more material than portions of the worn pad with more wear. The least amount of material is removed from the wafer 50 by the portion of the pad corresponding to the worn annular band. As a result, the polished surface 52 of the wafer is caused to have a generally “domed” shaped.

As illustrated in FIG. 2, “dishing” results in the wafer 60 having a generally concave polished surface 62. One potential reason for this occurring is that the polishing pad becomes embedded with abrasives (e.g., colloidal material from the slurry, debris from previously polished wafers, and debris from a retaining ring) causing the removal rate to increase in the areas of wear. The portions of the pad with more wear remove more material from the wafer during the polishing process than portions of the pad with less wear. As a result, more material to be removed from the center of the wafer 60 than from its edge 64 resulting in the polished surface 62 of the wafer having a generally “dished” shape.

In addition, due to an uneven distribution of mechanical and/or chemical forces near an edge of the wafer, a thickness profile at the peripheral edge of the wafer may be reduced, which is known as edge roll-off. Edge roll-off reduces the useful portion of the wafer available for device fabrication. Edge roll-off is generally controlled by adjusting an amount of slurry and/or a type of slurry applied to the pads.

When the flatness of the wafers becomes unacceptable (e.g., too “domed” or too “dished”), the worn polishing pad has to be replaced with a new one, or a pad dressing or conditioning operation needs to be performed to restore the pad to a useful state. These tasks add significant costs to the operation of the polishing machine because of the number of pads that need to be purchased, stored, and disposed of, but also because of the substantial amount of down time required to change the polishing pad or perform pad dressing/conditioning.

Because an excellent surface quality on both sides of a semiconductor wafer is required for a semiconductor wafer used in manufacturing of an advanced semiconductor devices, for example, 5 nanometer (nm) technology nodes or silicon-on-insulator (SOI) wafers, double-sided polishing machine is used to achieve required flatness and finishing on both sides of the semiconductor wafer. The double-sided polishing machine includes a first and second platen spaced from each other to form a gap therebetween. A wafer carrier is disposed in the gap formed between the first platen and the second platen. The first platen has a reaction plate, a polishing plate, and a bladder. A wafer placed in the wafer carrier is polished by the polishing plate as the polishing plate is rotated at a certain rotational speed to cause desired surface flatness. An internal pressure in the bladder is adjusted to deflect the polishing plate with respect to the wafer carrier for improving flatness of the polished surface.

Wafer flatness depends on many different conditions such as quality of an incoming wafer, kinetic settings (e.g., a rotational speed of a top platen, a rotational speed of a bottom platen, a rotational speed of a wafer carrier, and/or a number of gears to drive the wafer carrier at the determined rotational speed), a polishing pad aging, polishing slurry degradation, wear out conditions of a wafer carrier. In addition, a temperature, platen deformation, platen shapes, a polishing end point, polishing time, and so on, also affect wafer flatness quality in a double-sided polishing process.

During the double-sided polishing process, statistical process control (SPC) feedback data regarding wafer flatness control parameters is generated. The SPC feedback data is generated as charts. A process assistance engineer reviews the SPC feedback data charts and determines whether all wafer flatness control parameters are within a specification range as provided by a customer and/or for a particular application. Upon determining that one or more flatness control parameters are outside of the specification range, the process assistance engineer would change a platen profile (e.g., apply different rotational speed for the top platen and/or the bottom platen, and/or apply different pressure values to deflect the polishing plate of the top and/or bottom platens) and/or a step time for the double-sided polishing process. Since the platen profile and/or the step time are updated based on personal knowledge or experience of the process assistance engineer, from one process assistance engineer to another process assistance engineer, a large variation in flatness or other key parameters of the wafer occurs. Additionally, double-sided polishing of semiconductor wafers as currently being used may also increase production cost and/or production time.

Accordingly, there is a need for a double-sided polishing method in which the above-described problems associated with known methods for double-sided polishing of semiconductors wafers are addressed.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a polishing apparatus for double-sided polishing of semiconductor wafers is disclosed. The polishing apparatus includes a first platen, a second platen, a wafer carrier disposed within a gap formed between the first platen and the second platen, and a controller. The controller is configured to perform operations including determining whether a batch of the semiconductor wafers is loaded on the wafer carrier for double-sided polishing, and in accordance with the determining that the batch of semiconductor wafer is loaded, retrieving specification for the batch of semiconductor wafers. The operations include determining an amount of tuning required for one or more flatness control parameters based on the retrieved specification for the batch of semiconductor wafers, and based on the amount of tuning required for the one or more flatness control parameters, identifying, or generating a recipe to perform the double-sided polishing on the batch of the semiconductor wafers. The operations include upon performing the double-sided polishing on the batch of the semiconductor wafers according to the identified recipe, storing statistical process control (SPC) feedback data in a database to perform one or more additional iterations of the double-sided polishing on the batch of the semiconductor wafers.

In another aspect, a control system is operatively connected with a polishing apparatus for double-sided polishing of semiconductor wafers. The control system includes at least one memory configured to store instructions, and at least one processor configured to execute the stored instructions, which when executed, cause the at least one processor to perform operations including determining whether a batch of the semiconductor wafers is loaded on a wafer carrier of the polishing apparatus, and in accordance with the determining that the batch of semiconductor wafer is loaded, retrieving specification for the batch of semiconductor wafers. The operations include determining an amount of tuning required for one or more flatness control parameters based on the retrieved specification for the batch of semiconductor wafers, and based on the amount of tuning required for the one or more flatness control parameters, identifying, or generating a recipe to perform the double-sided polishing on the batch of the semiconductor wafers. The operations include causing the polishing apparatus to perform double-sided polishing on the batch of semiconductor wafers using the recipe, and receiving and storing statistical process control (SPC) feedback data in a database to perform one or more additional iterations of the double-sided polishing on the batch of the semiconductor wafers.

In yet another aspect, a method includes determining whether a batch of the semiconductor wafers is loaded on a wafer carrier of a double-sided polishing apparatus, and in accordance with the determining that the batch of semiconductor wafer is loaded, retrieving specification for the batch of semiconductor wafers. The method includes based on the retrieved specification for the batch of semiconductor wafers, determining an amount of tuning required for one or more flatness control parameters, and based on the amount of tuning required for the one or more flatness control parameters, identifying a recipe to perform the double-sided polishing on the batch of the semiconductor wafers, the recipe is identified based on analysis of historical statistical process control (SPC) feedback data. The method includes upon performing an iteration of the double-sided polishing on the batch of the semiconductor wafers according to the recipe, storing SPC feedback data corresponding to the performed iteration in a database.

### BRIEF DESCRIPTION OF THE DRAWINGS

FIG. 1 is a side elevation of a dome-shaped wafer;

FIG. 2 is a side elevation of a dish-shaped wafer;

FIG. 3 is an exploded view of a wafer double-sided polishing machine in accordance with some embodiments;

FIG. 4 is an example system block diagram to perform double-sided polishing of semiconductor wafers using dynamic control closed loop mechanism in accordance with some embodiments;

FIG. 5 is an example flow-chart of operations of an algorithm to select a new recipe for performing double-sided polishing of semiconductor wafers in accordance with some embodiments;

FIG. 6 is an example flow-chart of performing operations of for double-sided polishing of semiconductor wafers using dynamic control in accordance with some examples; and

FIG. 7 is an example block diagram of a distributed computing system including a double-sided polishing machine and a control system in accordance with some embodiments.

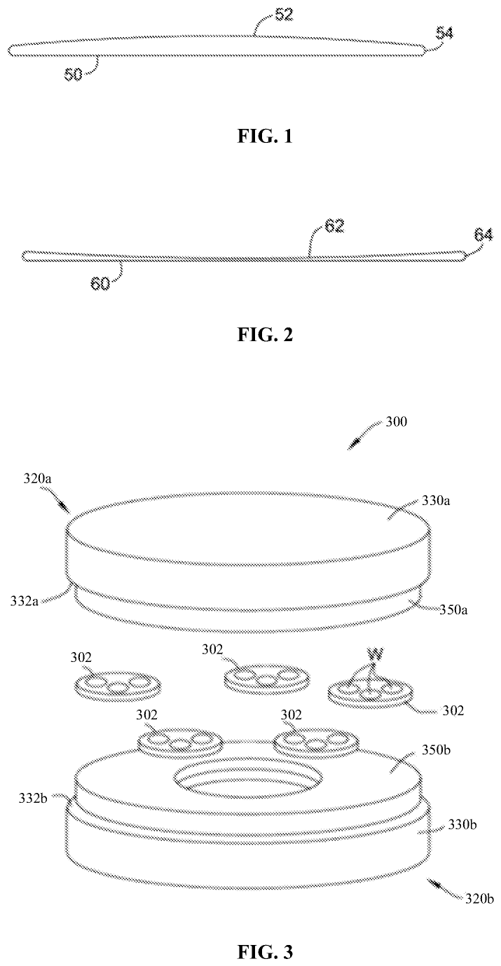

Like reference symbols in the various drawings indicate like elements.

### DETAILED DESCRIPTION

FIG. 3 is an exploded view of an example double-sided polishing machine in accordance with some embodiments. A schematic diagram of a portion of a double-sided polishing machine 300 is shown in FIG. 3. The double-sided polishing machine 300 is used to polish front and back sides of semiconductor wafers W sliced from one or more monocrystalline silicon ingots. It is contemplated that other types of double-sided polishing machine may also be used. The double-sided polishing machine 300 includes a plurality of generally annular wafer carriers 302 positioned between a generally annular first platen 320a and a generally annular second platen 320b.

Each wafer carrier 302 has at least one circular opening to receive a wafer W to be polished therein. In FIG. 3, each wafer carrier 302 is shown to have three openings to receive three wafers. However, a wafer carrier may have openings to receive wafers of any number and/or of any shape. The periphery of each wafer carrier 302 has a ring gear (not shown) engaged by a “sun” or an inner gear and an outer gear (not shown) of the double-sided polishing machine 300. The inner and outer gears are driven by a suitable drive mechanism to rotate the carrier at a selected speed.

The first platen 320a and second platen 320b are rotated at a selected rotational speed by a suitable drive mechanism (not shown) as is known in the art. In some embodiments, the double-sided polishing machine 300 includes a controller (such as the controller discussed below) that allows the operator to select a rotational speed for the first platen 320a that is different from a rotational speed for the second platen 320b. In some embodiments, the first platen 320a and second platen 320b are rotatable in the same direction or in opposite directions.

As shown in FIG. 3, the first platen 320a includes a reaction plate 330a and a first polishing plate 350a. The first polishing plate 350a is mounted in spaced relation to a bottom surface 332a of the reaction plate 330a. The second platen 320b includes a second reaction plate 330a and a second polishing plate 350b. The second polishing plate 350b is mounted in spaced relation to a surface 332b of the second reaction plate 350b.

The double-sided polishing machine 300 is shown here for an example only. However, any double-sided polishing machine, according to this or other embodiments, as described in U.S. Pat. No. 9,180,569, may be used. Content of U.S. Pat. No. 9,180,569 is incorporated herein by reference for all that it contains for all purposes.

The double-sided polishing machine 300 has a wafer carrier mounted between a first polishing plate of a first platen and a second polishing plate of a second platen. At least one wafer is positioned within the wafer carrier. One side of the wafer faces the first polishing plate, and the other side of the wafer faces the second polishing plate.

In operation, the first platen is lowered downward toward the second platen to bring the first polishing plate into contact with one side of the wafer and to bring the second polishing plate into contact with the other side of the wafer. A polishing slurry is applied to at least one of the polishing plates. The wafer carrier, the first polishing plate, and the second polishing plate are rotated. The first platen is forced downward during polishing at a selected “down force” so that the sides of the wafer are polished simultaneously by the respective polishing plates. Movement of the polishing plates in relation to the wafer polishes a portion of the wafer to form a polished surface.

While the semiconductor wafer is being polished, flatness of the polished surface is determined, for example, using a thickness end point detection unit (not shown in FIG. 3) of the double-sided polishing machine 300. The thickness end point detection unit may be communicatively or operably connected with a controller. The controller may be a controller of the double-sided polishing machine 300 or a controller associated with a control system that operates/controls the double-sided polishing machine 300.

The thickness end point detection unit may continuously (or in real time) measure thickness of the semiconductor wafer during double-sided polishing of the semiconductor wafer. By way of a non-limiting example, the thickness end point detection unit may include a non-contact wafer thickness gauge to measure thickness of the semiconductor wafer at multiple points on the surface of the semiconductor wafer. For example, the non-contact wafer thickness gauge may include a capacitance-based sensor, an ultrasonic sensor, a light amplification by stimulated emission of radiation (Laser) sensor, X-ray, and so on.

If it is determined that the flatness of the surface of the semiconductor wafer after the performing a double-sided polishing iteration is not within the required specification of a target wafer, then the process assistance engineer may generate a new recipe using one or more ML algorithms. The new recipe may set different values for one or more tunable double-sided polishing parameters than used during previous iteration for the next iteration of the double-sided polishing. The one or more tunable double-sided polishing parameters may include, for example, a top platen profile control pressure, a bottom platen profile control pressure, a rotational speed of the top platen and/or the bottom platen, a rotational speed of the wafer carrier, and/or step times associated with roll-off control, and so on, to ensure that the semiconductor wafer has flatness that meets the specification requirements corresponding to, for example, a thickness, flatness, doming, edge roll-off (ERO), and so on, as specified in a customer order.

Based on real time measurements of thickness at multiple points of the semiconductor wafer during double-sided polishing, a final thickness corresponding to various points on the surface of the semiconductor wafer (also referenced herein as target end points) may be predicted or estimated for the current recipe. If the predicted or estimated values of the final thickness corresponding to the target end points are not going to be within the required specification, then an alert or a notification may be generated.

The alert or the notification may include (or display) thickness corresponding to target end points as measured over time, predicted, or estimated values of thickness corresponding to target end points, and whether the process assistance engineer would like to interrupt the current iteration and/or generate and apply a new recipe for double-sided polishing of the semiconductor wafer that is according to the required specification of the target wafer.

Upon determining that the predicted or estimated values of thickness corresponding to target end points are not going to meet the specification requirement, then a new recipe may be automatically generated using the one or more ML algorithms and applied to perform the next iteration of double-sided polishing of the semiconductor wafer. A notification or an alert may be generated to inform the process assistance engineer of the new recipe and values of the tunable parameters in the new recipe.

Additionally, or alternatively, upon completion of an iteration of double-sided polishing on the batch of semiconductor wafers, a new recipe may be automatically generated using the one or more ML algorithms and applied to perform the next iteration of double-sided polishing of the semiconductor wafer.

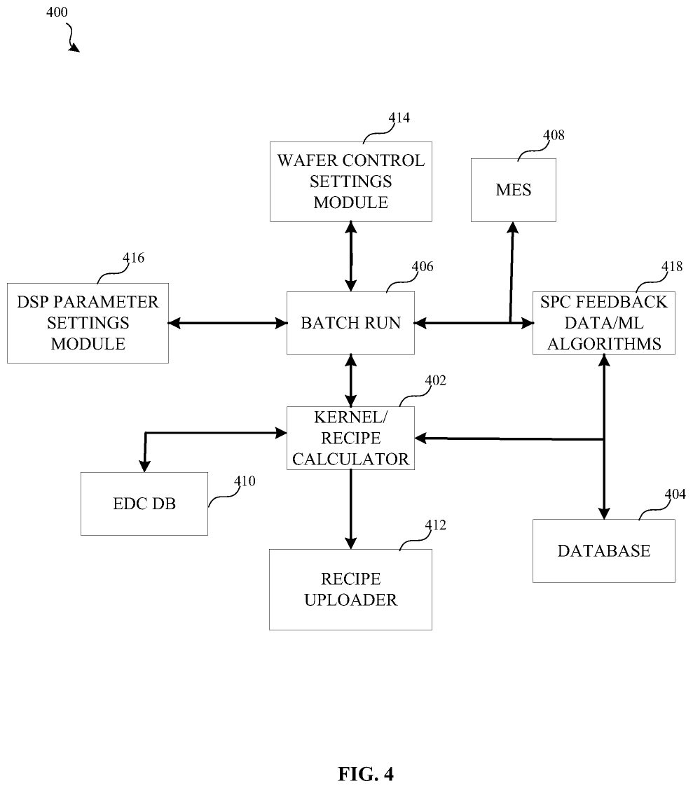

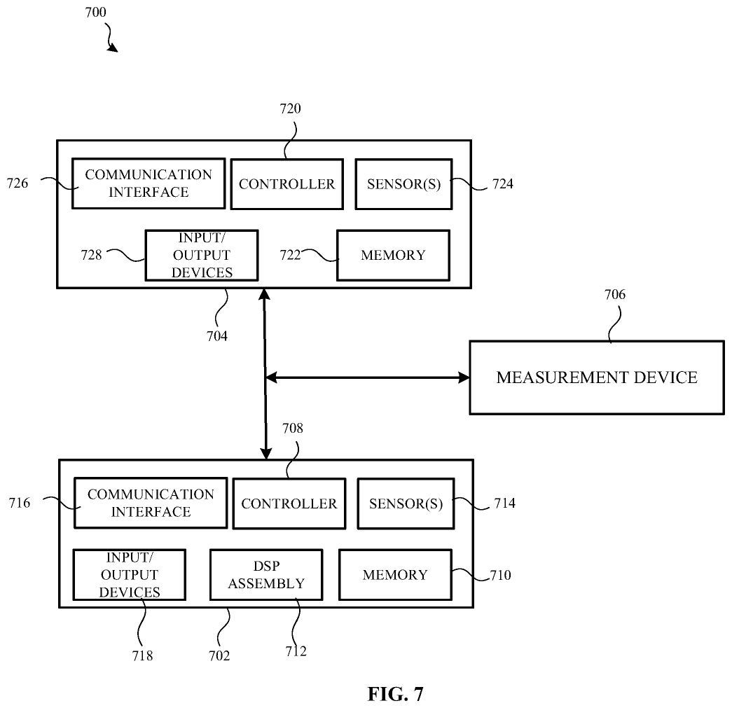

FIG. 4 is an example system block diagram 400 to perform double-sided polishing of semiconductor wafers using dynamic control closed loop mechanism according to some embodiments. Various blocks shown in the system block diagram 400 may be implemented as a separate module, a library, and/or an executable process. Additionally, or alternatively, one or more blocks may be combined in a single module, a library, and/or an executable process operating on a controller of the double-sided polishing machine, as shown in FIG. 7, or a controller of a control system operating the double-sided polishing machine, as shown in FIG. 7.

As shown in FIG. 4, a kernel module 402 may be configured to select or determine a recipe from a recipe database 404 to perform double-sided polishing of semiconductor wafers as a batch run, which is shown in FIG. 4 as 406. During the batch run 406, one or more semiconductor wafers (also referenced herein as a batch of semiconductor wafers) may be simultaneously processed for double-sided polishing using the double-sided polishing machine 300.

Initially, or while performing a first iteration of the double-sided polishing on the batch of semiconductor wafers, a recipe may be selected based on information corresponding to the batch of semiconductor wafers. By way of a non-limiting example, the information corresponding to the batch of semiconductor wafers may include a wafer identification (ID), a lot number of the batch of semiconductor wafers loaded on the double-sided polishing machine 300, and/or details regarding a customer (or a customer order), and so on. The information corresponding to the batch of semiconductor wafers and/or details regarding the customer (or the customer order) may be received (or retrieved) from a manufacturing execution system (MES) 408.

The MES 408 may include a database to store information corresponding to the batch of semiconductor wafers and/or details regarding the customer (or the customer order). The MES 408 thus provides an identity of each semiconductor wafer loaded in the double-sided polishing machine 300, and details of the customer for which double-sided polishing is being performed. Using a wafer ID as provided by the MES 408, the kernel 402 may receive additional details regarding specifications of the semiconductor wafer, such as resistivity of the batch of semiconductor wafers, and so on, from an engineering data center (EDC) database 410.

Based on the details from the customer (or the customer order), a desired target specification of the batch of semiconductor wafers, for example, a thickness and/or a flatness of the semiconductor wafers, may be obtained from the MES 408. The kernel 402 then may determine or select a recipe that sets a particular value for each of kinetic setting parameters (e.g., top and/or bottom platen profiles pressure values, and/or gear), step times for an edge roll-off control, and so on. The selected recipe may then be transmitted or communicated to a recipe uploader 412.

The recipe uploader 412 may then transmit or communicate the received recipe for loading on the double-sided polishing machine 300. While the double-sided polishing machine 300 performs double-sided polishing of the batch of semiconductor wafers according to the received recipe, a wafer control settings module 414 may provide (or control) values for wafer flatness parameters such as edge roll-off, dishing, and/or doming. The values for wafer flatness parameters may be provided in accordance with an epitaxy (EPI) process being performed on the double-sided polished semiconductor wafer. By way of a non-limiting example, the value for wafer flatness parameters may or may not be different from the target specification of the batch of semiconductor wafers.

Since the double-sided polishing on the batch of semiconductor wafers is performed in one or more iterations, in some embodiments, the wafer control settings module 414 may provide values for the wafer flatness parameters in different ranges for each iteration to achieve the target specification in increments. Corresponding to the wafer flatness parameters for each iteration, double-sided polishing (DSP) parameters settings module 416 may apply or adjust tunable DSP parameters accordingly. The DSP parameters settings module 416 may specify a step time for an edge roll-off control in minutes/seconds, one or more inline thickness sensor end points at which thickness is measured during double-sided polishing, one or more target end points on the surface of the semiconductor wafers to be polished, top platen profile control pressure, and/or a bottom platen profile control pressure, a rotational speed for a top platen, a rotational speed for a bottom platen, a rotational speed of a wafer carrier, a number of inner and/or outer gears that controls the rotational speed of the wafer carrier, and so on.

In one example, a value for the top platen profile control pressure may be between 3 to 50 bar and a value for the bottom platen profile control pressure may be between 0.5 to 1.05 bar. Similarly, a step time may be selected as between 0 to 30 minutes, and a thickness value for a target end point may be 770 to 778 micrometers during each iteration of the batch run. The DSP parameters and/or values specified for the DSP parameters, as described in the present disclosure, are for example only.

During the batch run 406, thickness corresponding to target end points may be continuously (or in real time) measured. Measurement data corresponding to thickness at target end points thus correspond with statistical process control (SPC) feedback data. The SPC feedback data may be transmitted to a database 418 for storing. The SPC feedback data may be associated with a batch run number (or a batch run ID) and then stored in the database 418. In some embodiments, and by way of a non-limiting example, the SPC feedback data may also be transmitted to the MES 408. The MES 408 may associate the SPC feedback data with the customer, the lot of the semiconductor wafers, and a batch run number (or a batch run ID).

As a non-limiting example, the SPC feedback data may be used for training one or more ML algorithms to predict wafer thickness and/or flatness values based on the current thickness and/or flatness measurements, particular wafer control settings, and/or DSP parameter settings. The one or more ML algorithms may be supervised and/or unsupervised ML algorithms. The SPC feedback data may be divided into two segments; SPC feedback data in one segment may be used for training a ML algorithm, and the other segment may be used for validating the trained ML algorithm before the ML algorithm is deployed in the production.

The SPC feedback data may include DSP parameter settings applied during each iteration of the batch run, thickness and/or flatness measurements at the beginning of an iteration, particular wafer control setting corresponding to the target wafer specification at the end of the iteration, and so on. Accordingly, one or more ML algorithms trained using the SPC feedback data may recommend a recipe to apply during the next iteration of the batch run. The one or more ML algorithms, as described herein, are contemplated as part of the kernel 402. However, the one or more ML algorithms may be separate from the kernel 402.

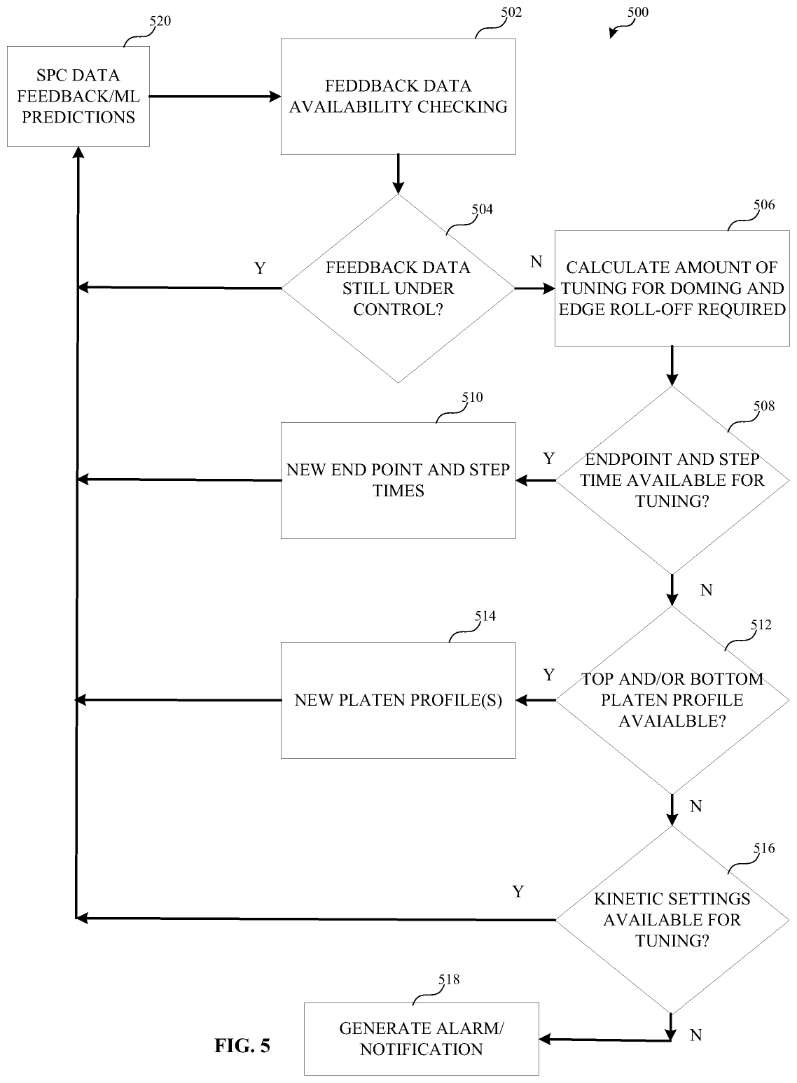

The kernel module 402 may then determine DSP parameter settings to be applied during the next iteration of the batch run based on the recipe suggested by the one or more ML algorithms. While the system block diagram 400 describes a closed loop control system for double-sided polishing of semiconductor wafers, FIG. 5 describes an example flow-chart of double-sided polishing of semiconductor wafers for the closed loop control system described using FIG. 4.

FIG. 5 is an example flow-chart of a method of double-sided polishing of semiconductor wafers, and in particular, a method to select a recipe based on which double-sided polishing parameter to tune during a particular iteration of the double-sided polishing. The method may be performed by the kernel 402 (or by the one or more ML algorithms) to select a recipe based on the current thickness and/or flatness measurement of the batch of semiconductor wafers, and/or a set of tunable DSP parameters to tune during the iteration.

As shown in a flow-chart 500, at 502, the kernel 402 may periodically check a status for a new batch of semiconductor wafers being loaded in the double-sided polishing machine 300. The kernel 402 may use a timer, and upon expiry of the timer, the kernel 402 may query the MES 408 to retrieve information corresponding to a customer (or a customer order) and/or a wafer ID. Upon determining that a new batch of semiconductor wafers is awaiting to perform double-sided polishing and/or being loaded to the double-sided polishing machine 300, the kernel may also retrieve data corresponding to specification of the batch of semiconductor wafers from the EDC database 410.

The specification of the batch of semiconductor wafers may include initial flatness, thickness, and/or resistivity of each semiconductor wafer of the batch of semiconductor wafers based on their respective wafer ID. Further, the kernel 402 may also retrieve a target specification corresponding to the desired thickness and/or flatness for the batch of semiconductor wafers based on the customer (or customer order) information. By way of a non-limiting example, the customer (or customer order) information may also include one or more wafer flatness control parameters. Accordingly, a recipe may be selected from the recipe database 404 corresponding to the current and target specifications of the batch of semiconductor wafers, and in which the one or more wafer flatness control parameters are tuned, as specified in the customer order information and/or to produce wafer having flatness and thickness as specified in the customer order information.

As stated above, the recipe database 404 stores recipes selected during earlier performed batch runs, along with the specification of semiconductor wafers in the beginning and/or the end of each double-sided polishing iteration, and DSP parameters and their respective values as applied during each double-sided polishing iteration. Accordingly, based on prediction of one or more ML algorithms, the kernel 402 may identify a particular recipe for loading and performing double-sided polishing of the batch of semiconductor wafers.

If at least one iteration of double-sided polishing has been previously performed on the batch of semiconductor wafers, then upon the timer expiry, the kernel 402 may check if new SPC feedback data is available in the database 418 based on the batch run number (or batch run ID). And the kernel 402 may select a recipe from the recipe database 404 corresponding to the current specification of the batch of semiconductor wafers at the end of the last iteration of the double-sided polishing, and the target specification of the batch of semiconductor wafers to further tune the one or more wafer flatness control parameters.

At 504, a decision regarding whether the new SPC feedback data is within the flatness control parameters as specified in the customer order or not is made. If it is determined that the new SPC feedback data is within the limits of the flatness control parameters as specified in the customer order, then the next iteration of the selected recipe may be performed, as shown in FIG. 5 as 520, and new SPC feedback data generated at the end of the iteration may be stored in the database 418, and operations as discussed above with reference to 502 may be repeated.

If it is determined at 504 that the new SPC feedback data is not within the limits of the flatness control parameters as specified in the customer order or expected flatness control parameters' target ranges, then, at 506, a determination or a calculation is made regarding how much further tuning is required for one or more flatness control parameters. The one or more flatness control parameters that are considered for tuning includes doming, dishing, and/or edge roll-off. Based on the calculated further tuning for the one or more flatness control parameters, the one or more ML algorithms may predict or recommend a new recipe including a different set of values for the one or more flatness control parameters. In some embodiments, the new recipe including a different set of values for the one or more flatness control parameters may be a recipe selected from the recipe database 404, if exists in the recipe database 404. Otherwise, a new recipe may be created and added to the recipe database 404.

At 508, a determination is made regarding whether an end point control and/or step time control are available for tuning. One or more tunable DSP parameters may have a minimum and a maximum value for effective flatness control. In one example, if doming is determined to be over a maximum allowed value, then thickness corresponding to an end point may be reduced to achieve the desired flatness. However, the thickness may be reduced such that the thickness remains within a minimum and a maximum value allowed for thickness.

While performing double-sided polishing of the batch of semiconductor wafers, different pressure values for the top and/or bottom platen profiles, rotational speeds for the top and/or bottom platens, and/or slurry settings, and so on, may be applied during different polishing step times. By way a non-limiting example, polishing step times may include L1 (ramp-up), L2 (warm-up), L3 (stock removal), L4 (edge roll-off control), L5 (semi-final slurry control), and so on. Polishing step times may be in minutes or seconds, for example, 0 to 30 minutes.

Accordingly, if further thickness tuning and/or a step time for further tuning are available, then the next iteration of the selected recipe may be performed, as shown in FIG. 5 as 520. The next iteration of the selected recipe may be performed based on new end point thickness and/or polishing step time determined at 510 for the calculated tuning of doming and/or edge roll-off as determined at 506. The new end point thickness and/or polishing step time may be as per recommendations by one or more ML algorithms, as described herein. At the end of the iteration, new SPC feedback data may be generated and stored in the database 518, and operations as discussed above with reference to 502 may be repeated.

If thickness cannot be further tuned, and/or step time for further tuning are not available, then at 512, a decision is made regarding whether top and/or bottom platen profiles are available to change flatness and/or doming of the batch of semiconductor wafers by applying pressure of different values on the semiconductor wafers. If the pads of top and/or bottom platens have not been worn-out, then different top and/or bottom platen profiles with different pressure values may be applied, as shown in FIG. 5 as 514, and next iteration of the selected recipe may be performed, as shown in FIG. 5 as 520. At the end of the iteration, new SPC feedback data may be generated and stored in the database 418, and operations as discussed above with reference to 502 may be repeated. Pressure values for the top and/or bottom platen profiles may be as recommended by one or more ML algorithms, as described herein.

If the pads of top and/or bottom platens have been worn-out, and/or if flatness of semiconductor wafers of the batch of semiconductor wafers has been severely out-of-range that can be corrected, then at 516, whether changing the top and/or bottom platens' rotational speed values, and/or a number of inner and/or outer gears corresponding to the wafer carrier's rotational speed may be determined. If it is determined that different rotational speed values for the top and/or bottom platens, and/or different number of inner and/or outer gears to change the wafer carrier's rotational speed are available to change wafer thickness and/or doming, then next iteration of the selected recipe may be performed, as shown in FIG. 5 as 520, according to the rotational speed values and/or the number of inner and/or outer gears as suggested in a recipe selected from the recipe database 404. At the end of the iteration, new SPC feedback data may be generated and stored in the database 418, and operations as discussed above with reference to 502 may be repeated. The rotational speed values for top and/or bottom platens, the rotational speed for the wafer carrier, and/or the number of inner and/or outer gears may be as recommended by one or more ML algorithms.

However, if it is determined that different rotational speed values for the top and/or bottom platens, different rotational speed values for the wafer carrier, and/or different number of inner and/or outer gears are not effective to change wafer thickness and/or doming, then an alert or a notification may be generated. The alert or the notification may indicate current flatness control measurements, the batch run number, the lot number of the batch of semiconductor wafers, details of the customer and/or customer order, and/or DSP parameters for the last batch run, and so on, for the process assistance engineer's intervention.

The same or different recipe may be selected from the recipe database 404 for execution of different iterations corresponding to the batch of semiconductor wafers. Further, a recipe and/or a respective value for each tunable DSP parameter of a set of tunable DSP parameters may be recommended by one or more ML algorithms, as described herein.

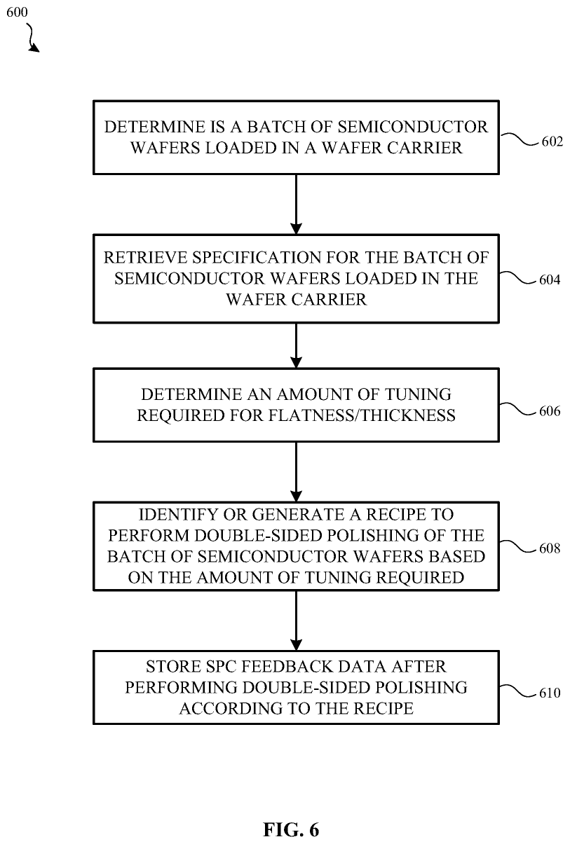

FIG. 6 is an example flow-chart 600 of performing operations of for double-sided polishing of semiconductor wafers using dynamic control according to some examples. As shown in the flow-chart 600, at 602, determination is made regarding whether a batch of semiconductor wafers is loaded on a wafer carrier of a double-sided polishing machine. The determination may be made in response to receiving a new order for double-sided polishing, and/or a new batch of semiconductor wafers being placed in the openings of the wafer carrier of the double-sided polishing machine, for example, using a robot operated in response to the received new order. In some examples, the presence of the semiconductor wafers may be detected using a sensor such as a laser sensor, a photoelectric sensor, and so on.

At 604, upon the new batch of semiconductor wafers being loaded on the wafer carrier, specification for the batch of semiconductor wafer loaded in the double-sided polishing machine may be obtained, as described herein using FIG. 4. As described herein, details from the customer orders and/or an ID of a lot of wafers may be used to retrieve specification for the batch of semiconductor wafers loaded in the double-sided polishing machine. The specification may include current/initial flatness, thickness, and/or size of the semiconductor wafers. The specification may also include material composition of the semiconductor wafers and/or resistivity details of the semiconductor wafers. Thus, the retrieved specification may include incoming or current specification for the batch of semiconductor wafers. The specification may also include target specification describing the desired thickness and/or flatness as per a customer order, a particular application, and so on.

At 606, based on the specification of the batch of semiconductor wafers retrieved at 604, an amount of tuning for the loaded batch of semiconductor wafers may be determined. The amount of required tuning may be determined to generate the wafers according to a thickness and/or a flatness as specified by the customer in the customer order. Based on the amount of required tuning, at 608, a recipe to perform double-sided polishing of the loaded batch of semiconductor wafers may be identified or generated. In some examples, the recipe, as described herein, may include details of a rotational speed of a top platen, a rotational speed of a bottom platen, a pressure value applied to the top platen to deflect the top platen, a rotational speed of a wafer carrier, a number of inner and/or outer gears corresponding to the rotational speed of the wafer carrier, and/or step times for various stages of the double-sided polishing process, and so on. The recipe may also include an amount and/or a type of slurry to use during double-sided polishing to control edge roll-off.

The recipe is suitably selected from recipes stored in a database, and each recipe stored in the database may also identify an initial specification or specifications of semiconductor wafers before the recipe is applied to perform the double-sided polishing process, and specification of the semiconductor wafers at the end of the double-sided polishing process as per the applied recipe. Accordingly, the recipe having the initial specification or specification of the semiconductor wafers before the recipe matching the incoming or current specification for the batch of semiconductor wafers loaded in the double-sided polishing machine, and/or having the specification of the semiconductor wafers at the end of the double-sided polishing process matching the target specification as retrieved at 604. In some examples, the recipe may be selected to generate the semiconductor wafers having the final specification as the target specification as retrieved at 604 in combination with another recipe that also may be applied to perform the double-sided polishing process.

If no recipe exists in the database matching the incoming specification and/or the target specification of the batch of semiconductor wafers loaded in the double-sided polishing machine, a new recipe may be generated using the one or more ML algorithms trained using historic SPC feedback data, as described herein. Using the trained ML algorithm, the new recipe may specify a pressure and/or a rotational speed of the top platen and/or the bottom platen, a rotational speed of the wafer carrier, a number of inner and/or outer gears corresponding to the rotational speed of the wafer carrier, a type and/or an amount of slurry, step time corresponding to various stages of the double-sided polishing process, and so on, based on which parameter(s)'s value to be changed/tuned.

At 610, after the recipe is uploaded to the double-sided polishing machine, and the double-sided polishing process is performed, the SPC feedback data is collected and stored in the database. The SPC feedback data, as described herein, may be used to generate, or identify another recipe for double-sided polishing of semiconductor wafers.

FIG. 7 is an example block diagram of a distributed computing system 700 including a double-sided polishing machine 702 and a double-sided polishing machine control system (or a control system) 704. In some examples, the system 700 is used for performing double-sided polishing of semiconductor wafers using the double-sided polishing machine 702 and controlling the double-sided polishing machine 702 using the control system 704. The control system 704 is a real-time data analyzing and classifying computer system that is configured to measure thickness and/or flatness of the semiconductor wafers, select a recipe to achieve the desired target specification for the semiconductor wafers, and control the double-sided polishing machine, as described herein. In some examples, the control system 704 may implement one or more modules or blocks described herein using FIG. 4.

The double-sided polishing machine 702 may include a controller 708 (also referenced herein as a double-sided polisher (DSP) controller 708), a memory 710, an assembly 712 to perform double-sided polishing of semiconductor wafers, one or more sensors 714, a communication interface 716, and/or an input/output devices 718, and so on. The control system 704 may include a controller 720, a memory 722, one or more sensors 724, a communication interface 726, and/or an input/output devices 728, and so on.

The DSP controller 708 may execute instructions stored in the memory 710. The DSP controller 708 may include one or more processing units such as a central processing unit, a microprocessor, a microcontroller, a field programmable gate array (FPGA), and/or an application-specific integrated circuit (ASIC), and so on. The controller 720 may execute instructions stored in the memory 722. The controller 720 may include one or more processing units such as a central processing unit, a microprocessor, a microcontroller, a field programmable gate array (FPGA), and/or an application-specific integrated circuit (ASIC), and so on.

The memory 710 and/or the memory 722 may be a random-access memory (RAM), a static RAM (SRAM), a dynamic RAM (DRAM), a hard disk, a solid-state drive, a flash drive, and so on. The one or more sensors 714 and/or 724 may include a capacitance-based sensor, an ultrasonic sensor, a light amplification by stimulated emission of radiation (Laser) sensor, X-ray, and so on, to measure thickness and/or flatness of semiconductor wafers. As described herein, the one or more sensors 714 and/or 724 may be included in a measurement device such as a non-contact wafer thickness gauge to measure thickness of the semiconductor wafer at multiple points on the surface of the semiconductor wafer.

The communication interface 716 and the communication interface 726 provide communication and exchange of data between the double-sided polishing machine 702 and the control system 704. The communication interface 716 and the communication interface 726 may include, for example, a local area network (LAN) or a wide area network (WAN) interface, dial-in-connections, cable modems, Internet connection, wireless, and special high-speed Integrated Services Digital Network (ISDN) lines.

The input/output device 718 and/or the input/output device 728 may include one or more displays for outputting information to a user and a keyboard, a mouse, a touchpad screen, and so on, to receive user input.

In some examples, the system 700 may also include a measurement device 706 configured to generate a profile of that wafer corresponding to thickness and/or flatness. More specifically, the measurement device 706 measures thickness and/or flatness of the wafer using, for example, optical wafer thickness gauges. The measurement device 706 may be in communication with the control system 704 through various wired or wireless interfaces including without limitation a network, such as a local area network (LAN) or a wide area network (WAN), dial-in-connections, cable modems, Internet connection, wireless, and special high-speed Integrated Services Digital Network (ISDN) lines. The measurement device 706 performs measurement corresponding to thickness and/or flatness of a wafer and reports the measurement data to the control system 704.

The embodiments described improve methods for double-sided polishing of semiconductor wafers. For example, double-sided polishing parameters are tuned based on one or more ML algorithms, which are trained using historical SPC feedback data collected during previously performed batch runs. Accordingly, prior negative outcomes associated with performing double-sided polishing depending on personal knowledge or experience of a process assistance engineer are reduced or eliminated.

When introducing elements of the present invention or the embodiment(s) thereof, the articles “a,” “an,” “the” and “said” are intended to mean that there are one or more of the elements. The terms “comprising,” “including,” and “having” are intended to be inclusive and mean that there may be additional elements other than the listed elements. The use of terms indicating a particular orientation (e.g., “top,” “bottom,” “side,” “down,” “up,” etc.) is for convenience of description and does not require any particular orientation of the item described.

As various changes could be made in the above constructions and methods without departing from the scope of the invention, it is intended that all matter contained in the above description and shown in the accompanying drawing[s] shall be interpreted as illustrative and not in a limiting sense.

What is claimed is:

1. A polishing apparatus for double-sided polishing of semiconductor wafers, the polishing apparatus comprising:
a first platen;
a second platen;
a wafer carrier disposed within a gap formed between the first platen and the second platen; and
a controller configured to perform operations comprising:
determining whether a batch of the semiconductor wafers is loaded on the wafer carrier for double-sided polishing;
in accordance with the determining that the batch of semiconductor wafer is loaded, retrieving specification for the batch of semiconductor wafers;
based on the retrieved specification for the batch of semiconductor wafers, determining an amount of tuning required for one or more flatness control parameters;
based on the amount of tuning required for the one or more flatness control parameters, identifying, or generating a recipe to perform the double-sided polishing on the batch of the semiconductor wafers; and
upon performing the double-sided polishing on the batch of the semiconductor wafers according to the identified recipe, storing statistical process control (SPC) feedback data in a database to perform one or more additional iterations of the double-sided polishing on the batch of the semiconductor wafers.

2. The polishing apparatus of claim 2, wherein retrieving specification for the batch of semiconductor wafers comprises retrieving at least one of: incoming specification for the batch of semiconductor wafers, current specification for the batch of semiconductor wafers, or target specification for the batch of semiconductor wafers.

3. The polishing apparatus of claim 1, wherein the one or more flatness control parameters include at least one of: edge roll-off, or doming.

4. The polishing apparatus of claim 1, wherein the identifying or generating the recipe comprises:
based on the retrieved specification for the batch of semiconductor wafers, identifying a set of double-sided polishing parameters for tuning and a respective value for each parameter of the set of double-sided polishing parameters to perform an iteration of the double-sided polishing on the batch of semiconductor wafers;
making predictions of a respective value of each of the one or more flatness control parameters based on identified set of double-sided polishing parameters for tuning and the respective value for each parameter of the set of double-sided polishing parameters;
based on the predictions of the respective value of each of the one or more flatness control parameters, identifying or generating the recipe corresponding to the identified set of double-sided polishing parameters for tuning and the respective values for each parameter.

5. The polishing apparatus of claim 4, wherein the identifying or generating the recipe further comprises determining whether the set of double-sided polishing parameters for tuning and the respective value for each parameter of the set of double-sided polishing parameters are available for performing the double-sided polishing on the batch of the semiconductor wafers.

6. The polishing apparatus of claim 4, wherein the set of double-sided polishing parameters for tuning includes at least one of: thickness or step time.

7. The polishing apparatus of claim 4, wherein the set of double-sided polishing parameters for tuning includes at least one of: a top platen profile or a bottom platen profile.

8. The polishing apparatus of claim 4, wherein the set of double-sided polishing parameters for tuning includes at least one of: a rotational speed of a top platen, a rotational speed of bottom platen, a number of inner pin gears, or a number of outer pin gears.

9. The polishing apparatus of claim 4, wherein making the predictions of the respective value of each of the one or more flatness control parameters comprises making predictions using one or more algorithms configured to predict the respective value of each of the one or more flatness control parameters based on historical SPC feedback data.

10. The polishing apparatus of claim 1, wherein the SPC feedback data includes incoming specification for the batch of semiconductor wafers, current specification for the batch of semiconductor wafers, or target specification for the batch of semiconductor wafers, a batch run number, information of a customer, information of a customer order, or batch ID of the semiconductor wafers.

11. A control system operatively connected with a polishing apparatus for double-sided polishing of semiconductor wafers, the control system comprising:
at least one memory configured to store instructions; and
at least one processor configured to execute the stored instructions, which when executed, cause the at least one processor to perform operations comprising:
determining whether a batch of the semiconductor wafers is loaded on a wafer carrier of the polishing apparatus;
in accordance with the determining that the batch of semiconductor wafer is loaded, retrieving specification for the batch of semiconductor wafers;
based on the retrieved specification for the batch of semiconductor wafers, determining an amount of tuning required for one or more flatness control parameters;
based on the amount of tuning required for the one or more flatness control parameters, identifying, or generating a recipe to perform the double-sided polishing on the batch of the semiconductor wafers;
causing the polishing apparatus to perform double-sided polishing on the batch of semiconductor wafers using the recipe; and
receiving and storing statistical process control (SPC) feedback data in a database to perform one or more additional iterations of the double-sided polishing on the batch of the semiconductor wafers.

12. The control system of claim 11, wherein retrieving specification for the batch of semiconductor wafers comprises retrieving at least one of: incoming specification for the batch of semiconductor wafers, current specification for the batch of semiconductor wafers, or target specification for the batch of semiconductor wafers.

13. The control system of claim 11, wherein the one or more flatness control parameters include at least one of: edge roll-off, or doming.

14. The control system of claim 11, wherein the identifying or generating the recipe comprises:
based on the retrieved specification for the batch of semiconductor wafers, identifying a set of double-sided polishing parameters for tuning and a respective value for each parameter of the set of double-sided polishing parameters to perform an iteration of the double-sided polishing on the batch of semiconductor wafers;
making predictions of a respective value of each of the one or more flatness control parameters based on identified set of double-sided polishing parameters for tuning and the respective value for each parameter of the set of double-sided polishing parameters;
based on the predictions of the respective value of each of the one or more flatness control parameters, identifying or generating the recipe corresponding to the identified set of double-sided polishing parameters for tuning and the respective values for each parameter.

15. The control system of claim 14, wherein the identifying or generating the recipe further comprises determining whether the set of double-sided polishing parameters for tuning and the respective value for each parameter of the set of double-sided polishing parameters are available for performing the double-sided polishing on the batch of the semiconductor wafers.

16. The control system of claim 14, wherein the set of double-sided polishing parameters for tuning includes at least one of: thickness, step time, a top platen profile, a bottom platen profile, a rotational speed of a top platen, a rotational speed of bottom platen, a number of inner pin gears, or a number of outer pin gears.

17. The control system of claim 14, wherein making the predictions of the respective value of each of the one or more flatness control parameters comprises making predictions using one or more algorithms configured to predict the respective value of each of the one or more flatness control parameters based on historical SPC feedback data.

18. The control system of claim 17, wherein the one or more algorithms are machine-learning algorithms trained using the historical SPC feedback data.

19. The control system of claim 11, wherein the SPC feedback data includes incoming specification for the batch of semiconductor wafers, current specification for the batch of semiconductor wafers, or target specification for the batch of semiconductor wafers, a batch run number, information of a customer, information of a customer order, or batch ID of the semiconductor wafers.

20. A method, comprising:
determining whether a batch of the semiconductor wafers is loaded on a wafer carrier of a double-sided polishing apparatus;
in accordance with the determining that the batch of semiconductor wafer is loaded, retrieving specification for the batch of semiconductor wafers;
based on the retrieved specification for the batch of semiconductor wafers, determining an amount of tuning required for one or more flatness control parameters;
based on the amount of tuning required for the one or more flatness control parameters, identifying a recipe to perform the double-sided polishing on the batch of the semiconductor wafers, the recipe is identified based on analysis of historical statistical process control (SPC) feedback data; and
upon performing an iteration of the double-sided polishing on the batch of the semiconductor wafers according to the recipe, storing SPC feedback data corresponding to the performed iteration in a database.
